(19) United States
(12) Patent Application Publication
(10) Pub. No.: US 2016/0111224 A1
(43) Pub. Date: Apr. 21, 2016

(54) PHOTOVOLTAIC DEVICE AND METHOD OF MANUFACTURE USING FEROVS

(71) Applicant: SWANSEA UNIVERSTIY, Singleton Park, Swansea (GB)

(72) Inventors: Cecile Charbonneau, Singleton Park (GB); Matthew Carnie, (US)

(73) Assignee: Swansea University, Singleton Park (GB)

(21) Appl. No.: 14/889,593

(22) PCT Filed: Apr. 30, 2014
(86) PCT No.: PCT/GB2014/000166

§ 371 Date: Nov. 6, 2015

(30) Foreign Application Priority Data
May 6, 2013 (GB) 1308135.1
May 28, 2013 (GB) 1309517.9

(51) Int. Cl. H01G 9/20; C09D 5/24; H01G 9/00

(52) U.S. Cl. CPC H01G 9/2031; H01G 9/0029; C09D 5/24

(57) ABSTRACT

The photovoltaic device is formed by coating a substrate with a transparent conducting oxide and then this layer is coated with a dioxide layer. The dioxide layer is then coated in a single step with a precursor solution including metal oxide nanoparticles and perovskites and this precursor can be heated to form a scaffold having a perovskite light absorber and electron transporter. A conductor is added to form a connection with the scaffold and it is envisaged that because a single step relatively low temperature process is used to form the scaffold then this can be painted onto a surface and cured in situ making it a very economical process.

### FIELD OF THE INVENTION

The invention relates to a photovoltaic device and a method of manufacture and in particular but not exclusively the device is based upon using perovskites.

### BACKGROUND OF THE INVENTION

An efficient solar cell must absorb over a broad spectral range, from visible to near-infrared (near-IR) wavelengths (350 to ˜950 nm), and convert the incident light effectively into charges. The charges must be collected at a high voltage with suitable current in order to do useful work. A simple measure of solar cell effectiveness at generating voltage is the difference in energy between the optical band gap of the absorber and the open-circuit voltage (V.) generated by the solar cell under simulated air mass (AM) 1.5 solar illumination of 100 mW cm⁻².

Dye-sensitized solar cells (DSSCs) have losses, both from electron transfer from the dye (or absorber) into the TiO₂, which requires a certain “driving force,” and from dye regeneration from the electrolyte, which requires an over potential. Efforts have been made to reduce such losses in DSSCs.

Inorganic semiconductor—sensitized solar cells have recently been used where a thin absorber layer of 2 to 10 nm in thickness, is coated upon the internal surface of a mesoporous TiO₂ electrode and then contacted with an electrolyte or solid-state hole conductor. These devices have achieved power conversion efficiencies of up to 6.3% However, in such systems there are low open circuit voltages which may be a result of the electronically disordered, low-mobility n-type TiO₂.

Perovskites are relatively underexplored in the area of solar cells and they provide a framework for binding organic and inorganic components into a molecular composite. It has been shown that layered perovskites based on organometal halides demonstrate excellent performance as light-emitting diodes and transistors with mobilities comparable to amorphous silicon.

The manufacture of solar cells based upon perovskites has several procedural steps which increases manufacturing costs because the process takes more time and energy. Typically the process involves providing a glass substrate having a conductive coating; usually fluorine doped tin oxide (FTO,) on one surface of the substrate. The FTO layer is coated with TiO₂, a sintered layer of metal oxide nanoparticles is coated on the TiO₂ and then there is heat treatment to drive off binders etc. to form a nanoporous film. The nanoporous film is coated with a precursor including a perovskite that again is heat treated so that the solution crystallizes to form a solid perovskite light absorber and electron transporter. As a final stage a hole transport layer and metal contacts are added.

The use of sintering to drive off binders etc. means that considerable time is taken to process the structure and also there is the increased cost of heating. The present invention seeks to overcome the problems of the prior art by providing a rapid and low temperature process in an extremely efficient photovoltaic device.

### SUMMARY OF THE INVENTION

According to a first aspect of the present invention there is provided a method of making a photovoltaic device including:

providing a substrate;

forming a compact layer on the substrate;

characterised in that the compact layer is coated with a precursor solution including metal oxide nanoparticles and perovskites and said precursor solution is heated to form a scaffold having a perovskite light absorber and electron transporter therein, following which a conductor is added to form a connection with the scaffold.

Preferably the compact layer is a metal oxide and in particular a dioxide.

It is preferred that the substrate is a layer of glass. However other materials such as metal or plastic may be used.

It is envisaged that the substrate has a coating of a transparent conducting oxide, which is typically fluorine doped tin oxide.

It is preferred that the dioxide layer is titanium dioxide.

Preferably the dioxide layer is applied by spray pyrolysis or spin coating a precursor solution followed by heat treatment.

It is envisaged that the metal oxide nanoparticles are selected from one or more of titania, alumina or zirconia. In particular the nanoparticles are Al₂O₃.

It is preferred that the perovskite is an organometal halide. Typically the organometal halide is of the structure ABX₃ where A and B are cations and X represents anions.

Preferably the percentage of metal oxide nanoparticles in the precursor solution containing the perovskite is 1 to 15% more preferable 1.5 to 12% and more particularly 2-7%.

It is envisaged that the perovskite solution is heat treated at a temperature of up to 200 degrees centigrade, more preferably 150 degrees centigrade and even more preferably between 100 and 120 degrees centigrade. The heating crystallizes the perovskite precursor to form the scaffold.

The compact layer and the coating may be provided as a single integral layer.

According to a further aspect of the invention there is provided a precursor solution to be applied to a dioxide coated substrate to form a photovoltaic device.

According to yet a further aspect of the invention there is provided a photovoltaic device formed by a method as described in a first aspect of the invention.

### BRIEF DESCRIPTION OF THE DRAWINGS

An embodiment of the present invention are described in more detail below, by way of illustrative example only, in conjunction with the accompanying figures, of which:

FIG. 1 shows: (A): a schematic representation of perovskite structure ABX₃ (A=CH₃NH₃, B=Pb, and X=Cl, I). (B) an SEM (scanning electron micrograph) view of a perovskite unit cell;

FIG. 2 shows: performance data of solutions where nanoparticles are in the precursor solution;

FIG. 3 shows: a scanning electron micrograph (SEM) of a plan view of a spin coated layer which has been heat treated and where alumina rich and poor areas are shown: and

FIG. 4 shows: a cross sectional SEM of a device coated with 5% by weight of nanoparticles in a perovskite precursor.

### DETAILED DESCRIPTION OF THE INVENTION

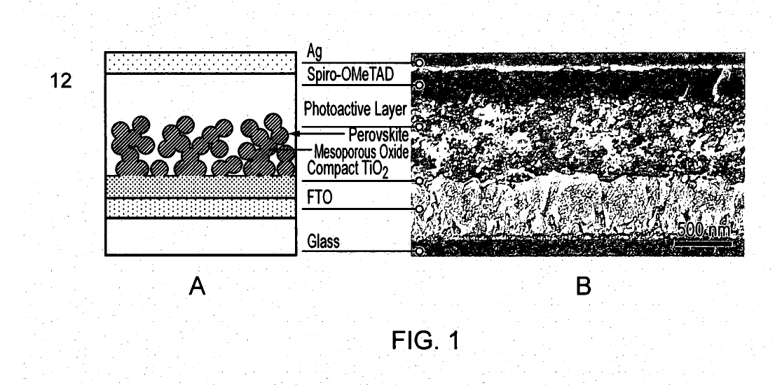

As can be seen in FIG. 1, solar cells were fabricated where a glass substrate is coated with a semitransparent fluorine-doped tin oxide (FTO). A compact layer of TiO₂ is then added and this acts as an anode. If glass is used the doped layer may be fluorine doped tin oxide on glass or indium tin oxide, which also may be provided on a plastic (e.g. PET or PEN) rather than glass.

The compact layer may be applied to the glass in the form of a paste comprising a metal oxide in a binder and a solvent so that the oxide can be printed on a surface. The metal may also be a wide band gap metal oxide such as SnO₂ or ZnO or TiO₂. An advantage of SnO₂ is that it is easier to obtain good particle interconnectivity which will minimise resistive losses and increase the efficiency of the sensitized solar cell. An advantage of using ZnO is that ZnO nanoparticles are readily available at low material cost. There are however, several advantages that are associated with using TiO₂, namely, TiO₂ is readily available, cheap, none-toxic and possesses good stability under visible radiation in solution, and an extremely high surface area suitable for dye adsorption. TiO₂ is also porous enough to allow good penetration by the electrolyte ions, and finally, TiO₂ scatters incident photons effectively to increase light harvesting efficiency.

The next layer that is added is the photoactive layer which included nanoparticles and a perovskite precursor. Electron injection into the anode (typically TiO₂) layer occurs and electron transport occurs through the titania film. When a non-conducting metal oxide is used, transport occurs through the perovskite material itself to the anode electrode, with the metal oxide nanoparticles acting as a scaffold to support the perovskite material. The nano-particles are placed directly in the organometal halide perovskite precursor solution prior to coating and both materials are laid down together. This precursor solution is heated at a much lower temperature than in known systems and by eliminating this high temperature step that the usual manufacturing processes use then the manufacture of these devices will be faster than those that are known. The process also uses less energy as the two usual heating steps namely sintering to drive of solvents and binders (500° C.) and then crystallizing the perovskite. (100° C.) are now combined into one heating step, typically at 100° C. This single step heating is unusual in that it still results in a scaffold with electron transfer properties.

The nano-particles are sold as a suspension either in water or IPA (isopropyl alcohol). These solvent are often incompatible with the perovskite precursor solution and so the nanoparticles should be suspended in the same solvent as the perovskite precursor solution. This is achieved via solvent exchange in a rotary evaporator. The preferred solvents for the organometal halide perovskite precursor solution are either DMF (N,N-Dimethylformamide) or y-butyrolactone. The precursor then consists of primary amine halide salt e.g. CH₃NH₃I (methyl ammonium lead iodide) and a lead halide salt e.g. PbCl₂ (lead chloride) dissolved in the solvent in the correct stoichiometry.

To complete the photoactive layer, the perovskite-coated porous electrode was further filled with the hole transporter, spiro-OMeTAD, via spin-coating and the spiro-OMeTAD forms a capping layer that ensures selective collection of holes at the silver electrode.

It is envisaged that this process will not be limited by substrate type so that devices will be manufacturable on glass or metal substrates. In addition, because of the low temperature nature of the process we envisage it possible to manufacture devices on plastic substrates.

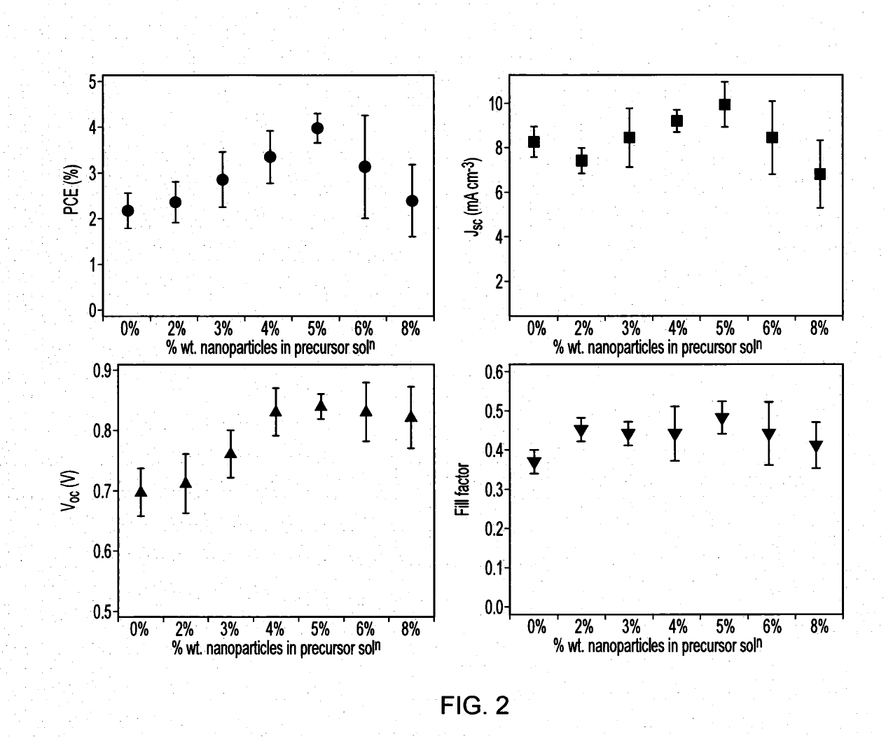

As shown in FIG. 2, the level of loading of the precursor with the nanoparticles has an impact on the efficiency of the device. A good performance is achieved when the precursor has a nanoparticle loading of 5% by weight and performance rises up to this level and declines afterwards. Further with this level of loading the efficiency of the devices formed is more consistent.

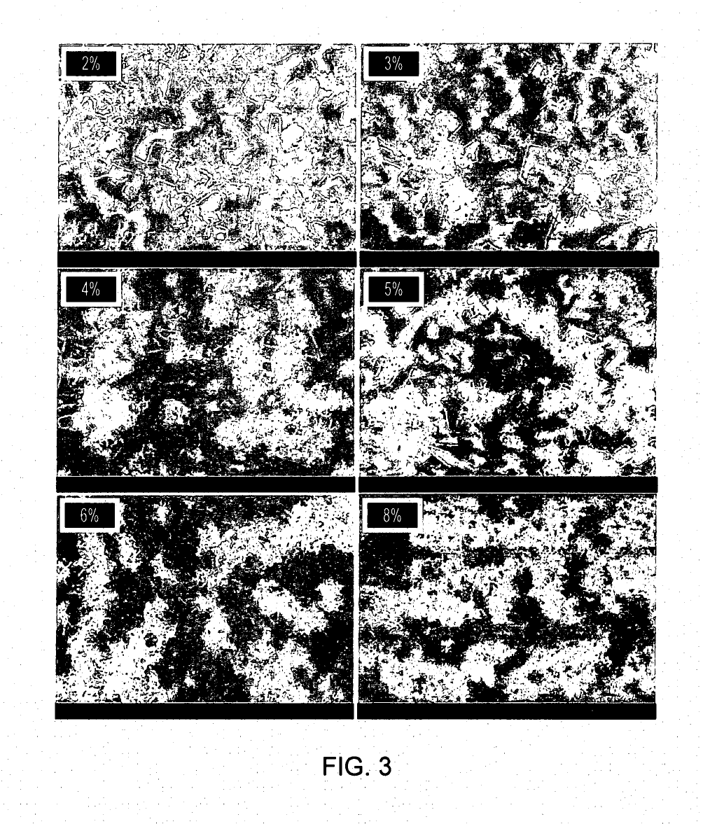

FIG. 3 shows a series of electron micrographs of where a mesoporous layer having nanoparticles, such as Al₂O₃— in a perovskite suspension has been sued. The perovskite suspension is CH₃NH₃PbI₂Cl. As can be seen the film formed is no homogenous with there being Al rich areas (light colouration) and Al poor regions (dark colouration). The separate images show the perovskite solution where there are nanoparticles in varying quantities and the precursor is applied directly onto the compact TiO₂ by spin coating and is then heat treated at 100 degrees centigrade.

For Al₂O₃-based cells, the electrons should remain in the perovskite phase until they are collected at the planar TiO₂-coated FTO electrode, and must hence are transported throughout the film thickness in the perovskite. The perovskite layer functions as both absorber and n-type component, transporting electronic charge out of the device with electrons being transferred to the TiO₂ (with subsequent electron transport to the FTO electrode through the TiO₂) and holes would be transferred to the spiro-OMeTAD (with subsequent transport to the silver electrode).

Typically charge collection in Al₂O₃-based devices was faster than in the TiO₂-based sensitized devices by a factor of >10, indicating faster electron diffusion through the perovskite phase than through the n-type TiO₂. Perovskites tend to form layered structures, with continuous two-dimensional metal halide planes perpendicular to the z axis and the lower dielectric organic components (methyl amine) between these planes. This quasi-two-dimensional confinement of the excitons can result in an increased exciton binding energy, which can be up to a few hundred millielectron volts.

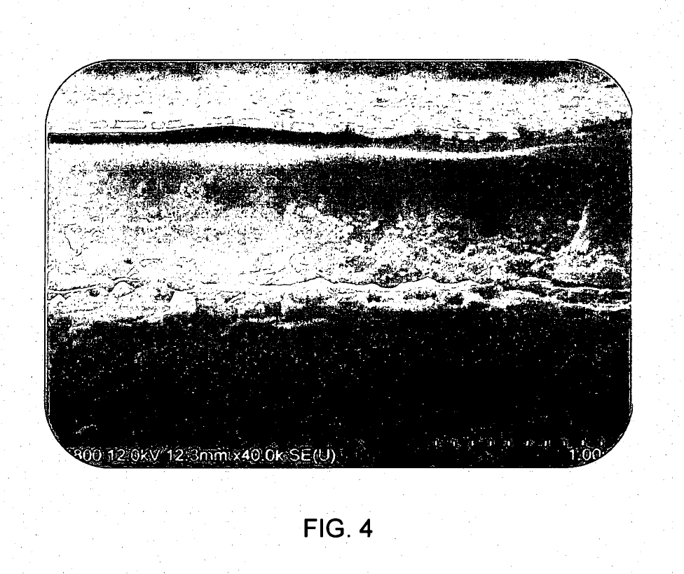

The application of a mesostructured insulating scaffold upon which extremely thin films of n-type and p-type semiconductors are assembled, termed the meso-superstructured solar cell (MSSC), has proven to be extraordinarily effective with an n-type perovskite. The light absorption near the band edge can be enhanced through carefully engineered mesostructures and by optimising the nanoparticle to perovskite ratio. As shown in FIG. 4, the loading of the perovskite precursor with a certain level of nanoparticles provides and optimised scaffold having a maximized surface area so that photovoltaic properties can be exploited as planar junction devices having efficiencies of around 1.8%. Also because a low temperature process can be used, it is envisaged that the precursor can be simply painted onto a substrate and heat treated in situ to provide the solid perovskite light absorber and transporter.

The invention has particular benefits in that it avoids having to use an expensive and time consuming processing step of sintering, typically at 500 degree centigrade. In this invention it allows for dilute solutions to be coated, typically spin coated onto a porous matrix e.g. Al₂O₃. The matrix may be in the form of a film which when heated at lower temperatures e.g. 120 degrees centigrade forms a framework as a result of evaporation of solvent and nucleation of perovskite. The perovskite grows into a continuous network so forming a scaffold for the solar cell and so provides a rapid and cost effective way of manufacturing solar cells.

Although the foregoing invention has been described in some detail by way of illustration and example, and with regard to one or more embodiments, for the purposes of clarity of understanding, it is readily apparent to those of ordinary skill in the art in light of the teachings of this invention that certain changes, variations and modifications may be made thereto without departing from the scope of the invention as described in the appended claims. Furthermore the invention is intended to cover not only individual embodiments that have been described but also combinations of the described embodiments.

1. A method of making a photovoltaic device the method including:
providing a substrate;
forming a compact layer on the substrate;
characterised in that the compact layer is coated with a precursor solution including metal oxide nanoparticles and perovskites and said precursor solution is heated to form a scaffold having a perovskite light absorber and electron transporter therein, following which a conductor is added to form a connection with the scaffold.

2. A method according to claim 1, wherein the substrate is a layer of glass, metal or plastic or a mixture thereof.

3. A method according to claim 1, wherein the substrate is coated with a transparent conducting oxide which typically is fluorine doped tin oxide.

4. A method according to claim 1 wherein the compact layer is a metal oxide.

5. A method according to claim 4, wherein the metal oxide is titanium dioxide.

6. A method according to claim 4, wherein the metal oxide layer is applied by spray pyrolysis or spin coating a precursor solution followed by heat treatment.

7. A method according to claim 1 wherein the metal oxide nanoparticles are selected from one or more of an oxide of titania, alumina or zirconia.

8. A method according to claim 7, wherein the metal oxide is AI2O3.

9. A method according to claim 1 wherein the perovskite is an organometal halide.

10. A method according to claim 1 wherein the percentage of metal oxide nanoparticles in the precursor solution containing the perovskite is 1 to 15% more preferable 1.5 to 12% and more particularly 2-7%.

11. A method according to claim 1 wherein once laid down on the dioxide layer, the precursor solution is heat treated at a temperature of up to 200 degrees centigrade, or 150 degrees centigrade, or and 100 and 120 degrees centigrade.

12. A method according to claim 1, wherein the compact layer and the coating are provided as a single integral layer.

13. A precursor solution to be applied to a dioxide coated substrate according to claim 1 to form a photovoltaic device, characterised in that said precursor solution comprises a mixture of metal oxide nanoparticles and perovskites.

14. A precursor solution according to claim 13, wherein the metal oxide nanoparticles are AI2O3 and the perovskite is methyl ammonium lead halide.

15. A precursor according to claim 13 in the form of a paint or coating that can be applied to a surface and then heated in situ to form the scaffold.

16. A photovoltaic device formed by a method according to claim 1.
